(19) United States
(12) Patent Application Publication
(10) Pub. No.: US 2017/0207777 A1
(43) Pub. Date: Jul. 20, 2017

(54) INTEGRATED CIRCUIT DEVICE AND DELAY CIRCUIT DEVICE HAVING VARIED DELAY TIME STRUCTURE

(71) Applicant: MACRONIX INTERNATIONAL CO., LTD., HSINCHU (TW)

(72) Inventors: Su Chueh LO, Hsinchu City (TW); Chia-Feng CHENG, Hsinchu City (TW)

(73) Assignee: Macronix International Co., Ltd.

(21) Appl. No.: 14/996,338

(22) Filed: Jan. 15, 2016

(51) Int. Cl. H03K 5/135; H03K 5/14

(52) U.S. Cl. CPC H03K 5/135; H03K 5/14; H03K 2005/00019

(57) ABSTRACT

An electronic circuit includes a forward delay circuit having a plurality of first stages. Each of the first stages is configured to introduce a delay time, the delay times of the first stages being varied. The electronic circuit further includes a control circuit coupled to the forward delay circuit, and a backward delay circuit coupled to the control circuit and having a plurality of second stages. Each of the second stages is configured to introduce a delay time, the delay times of the second stages being varied.

### FIELD

Disclosed embodiments relate to an integrated circuit device having a delay circuit device and, more particularly, to an integrated circuit device including a delay circuit device having a varied delay time structure.

### BACKGROUND

As the operating frequency of electronic system-on-chip (SoC) applications increases, clock skew may increase. Such SoC applications typically include de-skew clock circuits to ensure clock synchronization. Among various de-skew clock circuits, because of its relatively simple circuit structure, a synchronous mirror delay (SMD) circuit has been more suitable for applications that require fast locking and low power consumption, than a phase-locked loop (PLL) circuit or a delay-locked loop (DLL) circuit.

FIG. 1A is a block diagram of a conventional integrated circuit chip 100. Chip 100 includes an input buffer 102, a clock driver 104, an output buffer 106, and a circuit block 108, e.g., a sensing amplifier. Because each of the elements of chip 100 has impedance, they introduce signal delay. For example, input buffer 102 receives a clock signal from an external clock (Ext Clk) 110, passes the clock signal to clock driver 104, and introduces an internal delay time period Td1. In response, clock driver 104 generates an internal clock (Int Clk) signal to control the data output of output buffer 106, which buffers data output by circuit block 108. Clock driver 104 introduces an internal delay time period Td2. Output buffer 106, which has an internal delay time period Td3, is triggered by the internal clock signal Int Clk, and outputs data to a data bus (DQ) 112. As a result of the delays Td1, Td2, and Td3, the total delay between external clock 110 and data bus 112 amounts to Td1+Td2+Td3. As a result, the output of the data by chip 100 is delayed relative to the external clock signal Ext Clk.

FIG. 1B shows a schematic waveform diagram, in which waveform 120 represents the external clock signal Ext Clk of external clock 110, waveform 122 represents the internal clock signal Int Clk of clock driver 104, and waveform 124 represents data output to data bus 112. As shown in FIG. 1B, the rising (or falling) edges of the internal clock signal waveform 122 lag the rising (or falling) edges of the external clock signal waveform 120 due to the delays introduced by input buffer 102 and clock driver 104. For example, waveform 120 transfers to a low level at time T1 while waveform 122 transfers to a low level at time T2, later than time T1. Also, due to the delay introduced by output buffer 106, output buffer 106 outputs data to data bus 112 at time T3, which further lags behind the falling edge, at time T2, of waveform 122. As shown in FIG. 1B, the total delay between external clock 110 and data bus 112 is Td1+Td2+Td3. As a result, a read operation by chip 100 may not be accurate due to clock skew caused by the delays.

### SUMMARY OF EMBODIMENTS

According to a first aspect of the present disclosure, there is provided an electronic circuit. The electronic circuit includes a forward delay circuit having a plurality of first stages. Each of the first stages is configured to introduce a delay time, the delay times of the first stages being varied. The electronic circuit further includes a control circuit coupled to the forward delay circuit, and a backward delay circuit coupled to the control circuit and having a plurality of second stages. Each of the second stages being configured to introduce a delay time, the delay times of the second stages being varied.

According to a second aspect of the present disclosure, there is provided an integrated circuit including an input port to receive a signal, an output buffer to output data, and a delay circuit coupled to the input port and the output buffer. The delay circuit is configured to coordinate a first time when the input port receives the signal with a second time when the output buffer outputs the data. The delay circuit includes a forward delay circuit having a plurality of first stages. Each of the first stages is configured to introduce a delay time, the delay times of the first stages being varied. The delay circuit further includes a control circuit coupled to the forward delay circuit, and a backward delay circuit coupled to the control circuit and having a plurality of second stages. Each of the second stages is configured to introduce a delay time, the delay times of the second stages being varied.

According to a third aspect of the present disclosure, there is provided a circuit chip including an input buffer to receive a first clock signal, an output buffer to output data, a clock driver to generate a second clock signal to control the output buffer to output the data, and a delay circuit coupled between the input buffer and the clock driver. The delay circuit is configured to coordinate a first time when the input buffer receives the first clock signal with a second time when the output buffer outputs the data. The delay circuit includes a forward delay circuit having a plurality of first stages. Each of the first stages is configured to introduce a delay time, the delay times of the first stages being varied. The delay circuit further includes a control circuit coupled to the forward delay circuit, and a backward delay circuit coupled to the control circuit and having a plurality of second stages. Each of the second stages is configured to introduce a delay time, the delay times of the second stages being varied.

### BRIEF DESCRIPTION OF THE DRAWINGS

Reference will now be made, by way of example, to the accompanying drawings which show example embodiments of the present application, and in which:

FIG. 1A is a block diagram of a conventional integrated circuit chip:

FIG. 1B is a schematic waveform diagram showing waveforms of the circuit chip in FIG. 1A;

FIG. 2A is a block diagram of an integrated circuit chip having a delay circuit;

FIG. 2B is a schematic waveform diagram showing waveforms of the circuit chip in FIG. 2A;

FIG. 2C is a schematic diagram of the circuit chip in FIG. 2A;

FIG. 2D is an exemplary timing diagram of the circuit chip in FIG. 2C;

FIG. 3A is a schematic diagram of the circuit chip in FIG. 2A operated at a high frequency and including structure of an delay circuit;

FIG. 3B is a schematic diagram of the circuit chip in FIG. 2A operated at a low frequency and including the delay circuit structure shown in FIG. 3A;

FIG. 4 is a schematic diagram of a circuit chip including structure of an delay circuit according to an embodiment;

FIG. 5A is a schematic diagram of a circuit chip, operated at a high frequency and including structure of an delay circuit according to another embodiment;

FIG. 5B is a schematic diagram of the circuit chip shown in FIG. 5B, operated at a low frequency; and

FIG. 6 is a schematic diagram of a circuit chip including structure of a delay circuit according to an embodiment.

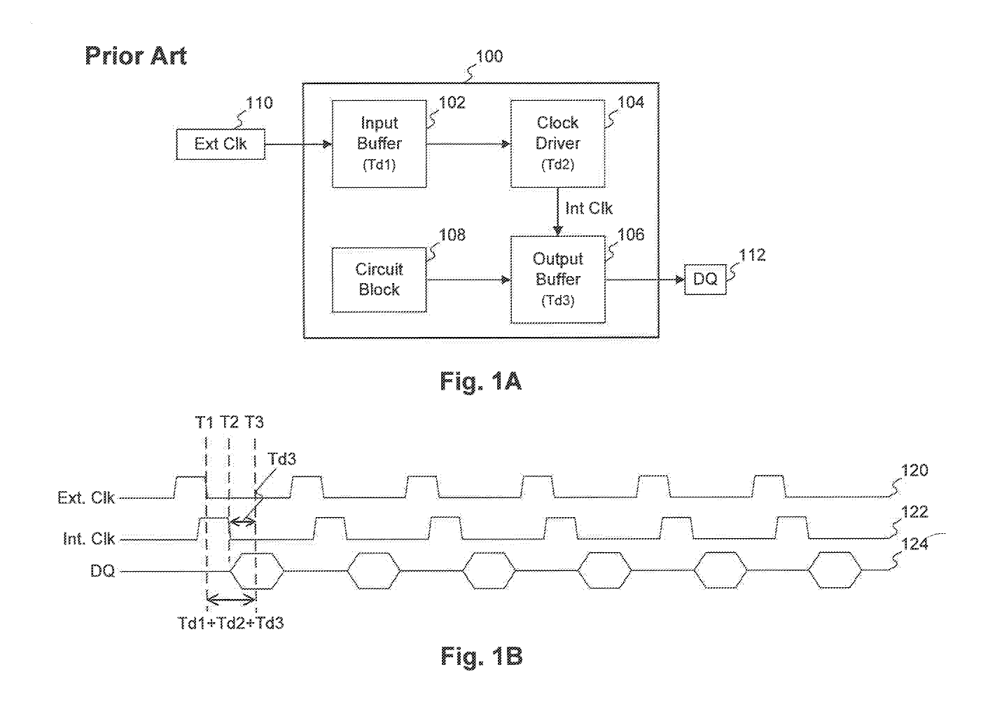

### DESCRIPTION OF EMBODIMENTS

Hereinafter, embodiments consistent with the disclosure will be described with reference to the drawings. Wherever possible, the same reference numbers will be used throughout the drawings to refer to the same or like parts.

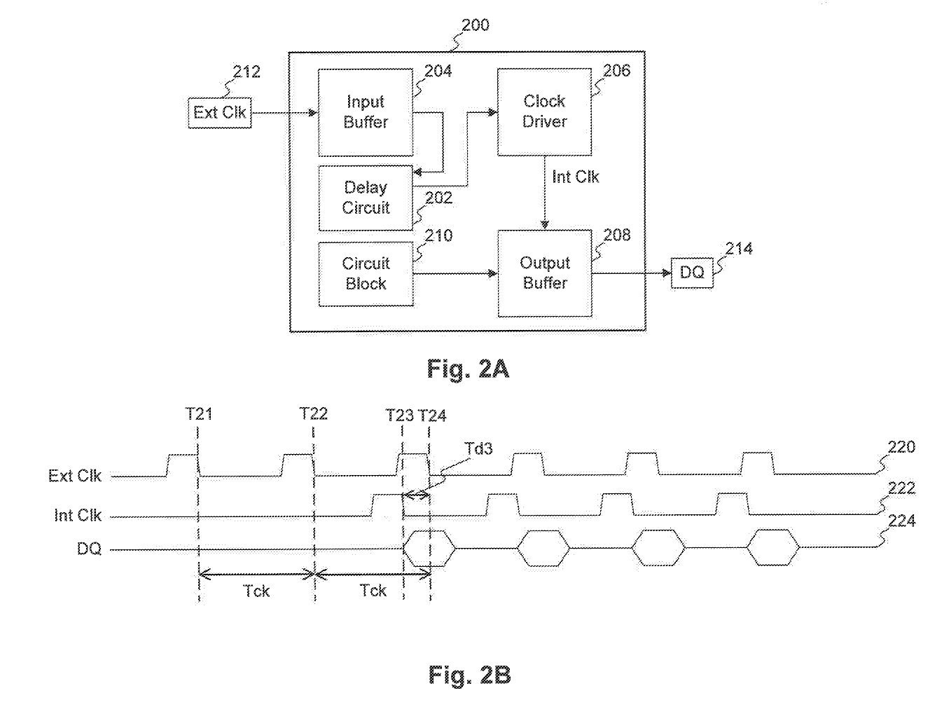

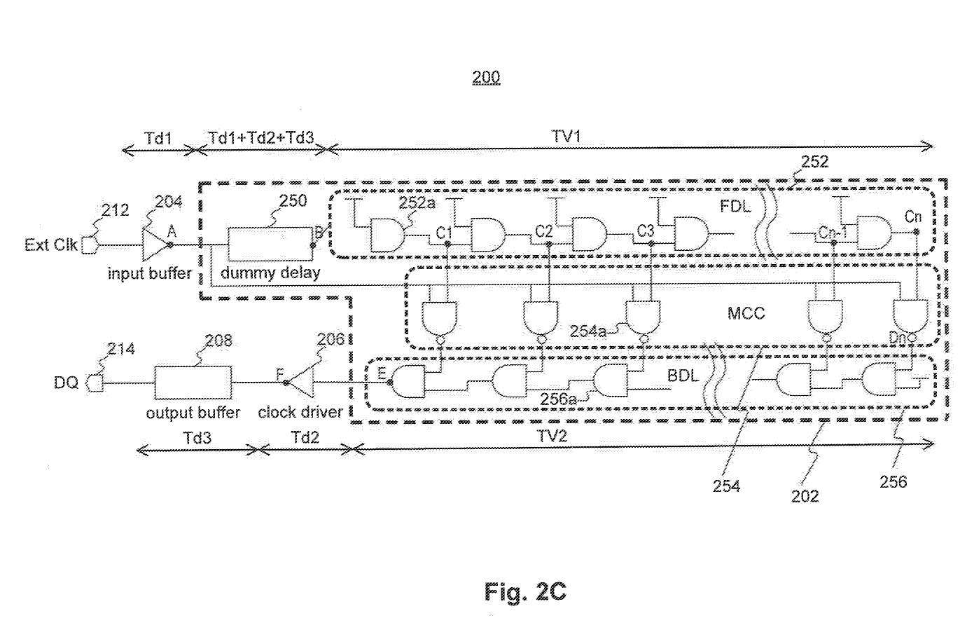

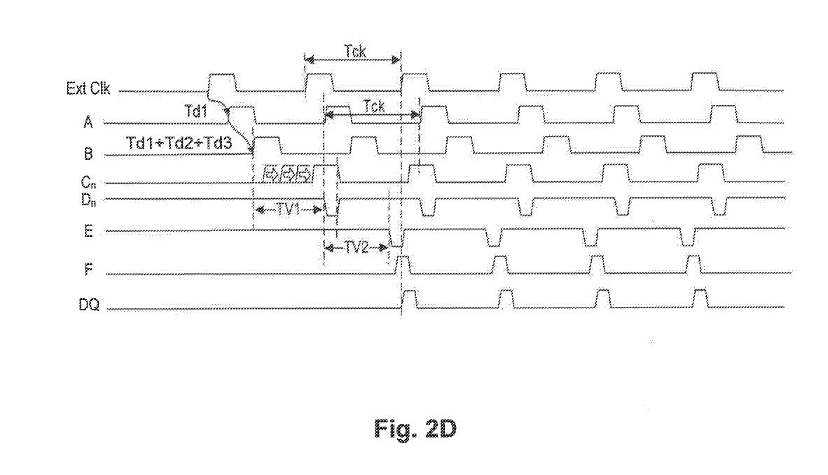

FIG. 2A is a block diagram of an integrated circuit chip 200 including a delay circuit 202. Delay circuit 202 may be a synchronous mirror delay circuit. Circuit chip 200 further includes an input buffer 204, a clock driver 206, an output buffer 208, and a circuit block 210. Chip 200 receives a clock signal Ext Clk from an external clock 212 and outputs data to a data bus (DQ) 214. In the illustrated embodiment, input buffer 204 receives and buffers the external clock signal Ext Clk, outputs the buffered clock signal to delay circuit 202, and introduces an internal delay time period Td1. Clock driver 206 receives a delayed clock signal generated by delay circuit 202, and in response generates an internal clock signal Int Clk to control the output of output buffer 208. In the process of generating the internal clock signal Int Clk, clock driver 206 introduces an internal delay time period Td2. Output buffer 208, which introduces an internal delay time period Td3, is triggered by the internal clock signal to output data to data bus 214. To synchronize the external clock signal Ext Clk of external clock 212 with data output to data bus 214, delay circuit 202 introduces a delay time period equal to 2Tck−(Td1+Td2+Td3), where Tck is one clock cycle of the external clock signal.

FIG. 2B shows a schematic waveform diagram, in which waveform 220 represents external clock signal Ext Clk generated by external clock 212, waveform 222 represents internal clock signal Int Clk generated by clock driver 206, and waveform 224 represents data output to data bus 214. As shown in FIG. 2B, the first, second, and third falling edges of the external clock signal Ext Clk in waveform 220 appear at times T21, T22, and 124, respectively. The external clock signal Ext Clk is synchronized with data output DQ at time T24, at which time data bus 214 is ready to receive data, i.e., on the falling edge of the external clock Ext Clk. In some embodiments, synchronization includes a degree of phase error. Phase error in synchronization is discussed below. The total delay between the falling edge of the external clock signal Ext Clk at time T21 and the first data output to data bus 214 is 2Tck. Due to the delay time period introduced by delay circuit 202, clock driver 206 outputs the internal clock signal Int Clk having a first falling edge at time T23. The time period between time T23 and time T24 when the data is output to data bus 214 is the delay Td3 introduced by output buffer 208.

FIG. 2C is a schematic diagram of circuit chip 200, showing delay circuit 202 in greater detail. Referring to FIG. 2C, delay circuit 202 includes a dummy delay circuit 250, a forward delay circuit (FDC) 252, a mirror control circuit (MCC) 254, and a backward delay circuit (BDC) 256. Dummy delay circuit 250 is configured to delay the external clock signal Ext Clk received via input buffer 204 by a pre-determined time period. In the illustrated embodiment, dummy delay circuit 250 introduces a delay time of Td1+Td2+Td3. FDC 252 includes a plurality of gates 252a, also referred to herein as stages. Each of gates 252a may be an AND gate and introduces the same delay time Td_gd. MCC 254 includes a plurality of gates 254a, which may be NAND gates. BDC 256 includes a plurality of gates 256a, also referred to herein as stages, each of which may be an AND gate and introduces the same delay time Td_gd. The output of each of gates 252a of FDC 252 is coupled to an input of one of gate 254a of MCC 254. The output of each of gates 254a is coupled to an input of one of gate 256a of BDC 256. Pulses of external dock signal Ext Clk received via input buffer 204 propagate forward through FDC 252, to MCC 254, and then propagate backward through BDC 256 to dock driver 206.

Delay times introduced by the elements of FIG. 2C are shown immediately above or below those elements. That is, input buffer 202 introduces a delay of Td1, dummy delay circuit 250 introduces a delay of Td1+Td2+Td3, FDC 252 introduces a delay of TV1=Tck−(Td1+Td2+Td3), BDC 256 introduces a delay of TV2=Tck−(Td1+Td2+Td3), clock driver 206 introduces a delay of Td2, and output buffer 208 introduces a delay of Td3. Thus, the total delay of circuit chip 200 including delay circuit 202 is Td1+(Td1+Td2+Td3)+[Tck−(Td1+Td2+Td3)]+[Tck−(Td1+Td2+Td3)]+Td2+Td3, which is equal to 2Tck.

In some embodiments, chip 200 may need to operate in a wide range of frequency. When circuit chip 200 is operated at a relatively high frequency, e.g., 200 MHz, which corresponds to a short external clock cycle, it is not able to tolerate any significant phase error, and the synchronized clock output requires high accuracy. That is, the external clock signal is coordinated with the data output with higher accuracy. However, when circuit chip 200 is operated at a lower frequency, e.g., 50 MHz, which corresponds to a relatively longer external clock cycle, it is generally able to tolerate a greater phase error. That is, the external clock signal is coordinated with the data output with lower accuracy. For example, in one embodiment, a high frequency application may tolerate up to a 5% phase error and a low frequency application may tolerate up to a 10% phase error. One major contributor to the phase error is the resolution of the FDC/BDC delay, which directly relates to the delay time, Td_gd, of each stage, of delay circuit 202. Cumulative error introduced by the respective stages of each of FDC 252 and BDC 256 is referred to herein as quantization error. To minimize the quantization error, the delay time of each stage in FDC 252 and BDC 256 is configured to be very short.

Moreover, when circuit chip 200 is operated at a lower frequency, delay circuit 202 is configured to generate a longer delay because, as explained above, its total delay time is 2[Tck−(Td1+Td2+Td3)]. A total number of gates (stages) in FDC 252 and BDC 256 of delay circuit 202 is determined by the lowest frequency at which delay circuit 202 is required to operate. If circuit chip 200 is configured to operate at both high and low frequencies, not only do each stage of delay in FDC 252 and BDC 256 need to introduce a short delay to improve accuracy for high frequency applications, but also the total potential delay needs to be long enough for low frequency applications. As a result, each of FDC 252 and BDC 256 is designed to have as many stages (gates) having an equal, short delay, as required for an anticipated low frequency application, which cause delay circuit 202 to occupy a large circuit area and consume more power.

FIG. 2D shows a timing diagram for operation of circuit 200 shown in FIG. 2C. In the timing diagram and as also shown in FIG. 2C, A is the output of input buffer 202, B is the output of dummy delay circuit 250, Cn is the output of the nth gate of FDC 252, Dn is the output of the nth gate of MCC 254, E is the output of BDC 256, and F is the output of clock driver 206. As shown in FIG. 2D, input buffer 202 introduces a delay of Td1, so that a time difference between a pulse of external clock signal Ext Clk and a corresponding pulse of output A of input buffer 202 is equal to Td1. Similarly, dummy delay circuit 250 introduces a delay of Td1÷Td2+Td3, so that a time difference between a pulse of output A of input buffer 202 and a corresponding pulse of output B of dummy delay circuit 250 is equal to Td1+Td2+Td3. FDC 252 introduces a delay of TV1=Tck−(Td1+Td2+Td3). Depending on the length Tck of a cycle of external clock signal Ext Clk, the clock signal traverses different numbers of gates 252a of FDC 252. When circuit 200 is used at a higher frequency, and correspondingly shorter Tck, the delay introduced by FDC 252, i.e., TV1=Tck−(Td1+Td2+Td3), is also shorter. As a result, the clock signal needs to traverse fewer gates of FDC 252.

In one embodiment, it is assumed that the clock signal traverses a number n of gate 252a, where n is an integer equal to or greater than one. Referring to FIGS. 2C and 2D, the output Dn at the nth gate of MCC 254 is controlled by outputs Cry and A. Output A controls which gate(s) 252a will be traversed.

As an example, when both outputs of A and Cn include logic “1”, MCC 254 outputs logic “0” at output Dn. As shown in FIG. 2D, a clock cycle of output A is Tck. Because the delay between output A and output B is Td1+Td2+Td3, when output A rises and output Dn falls at the same time, the delay between output B and output Dn is equal to TV1=Tck−(Td1+Td2 Td3). BDC 256 introduces a delay such that a delay between output Dn and the output of BDC 256 at E is equal to TV2=Tck−(Td1+Td2+Td3).

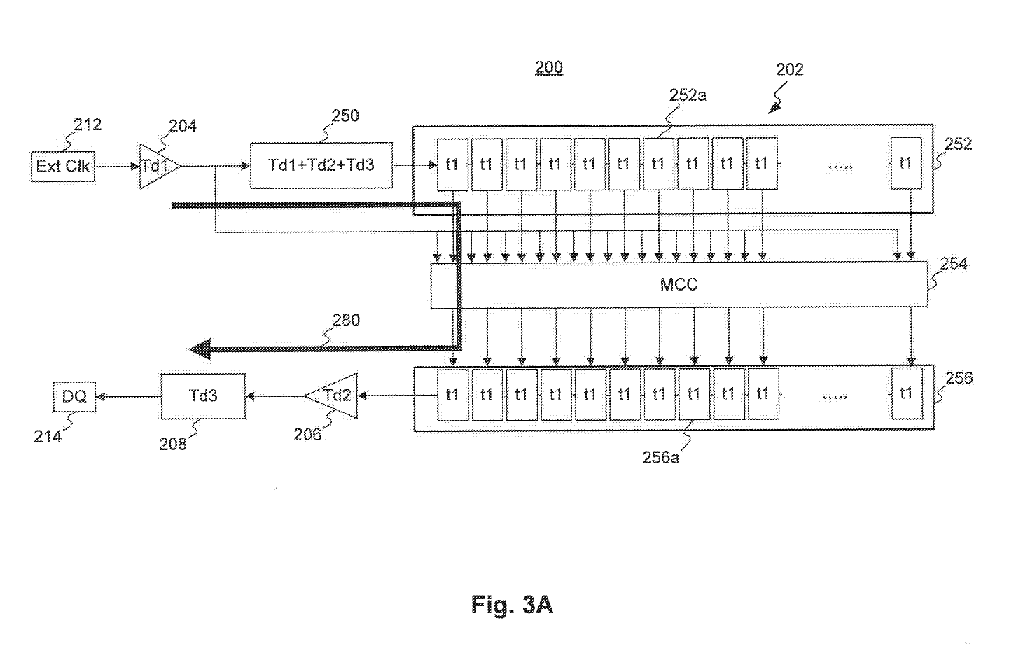

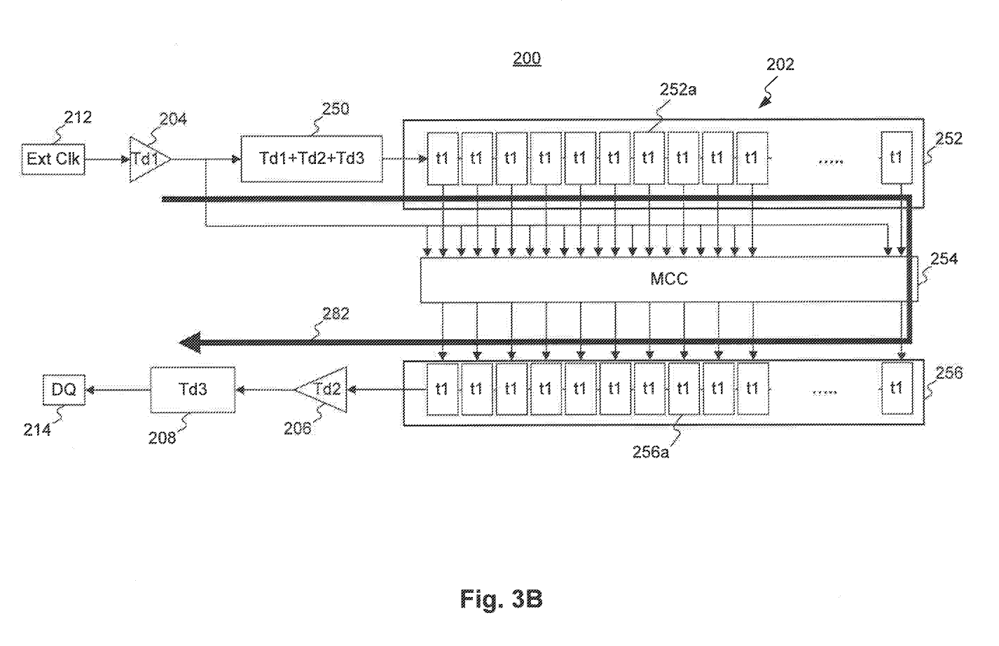

FIG. 3A shows a schematic diagram of circuit chip 200, in which the delay time of each stage of FDC 252 and BOC 256 is indicated on the element. The delay times of input buffer 204, clock driver 206, and output buffer 208 are the same as those shown in FIG. 2C, and are also shown in FIG. 3A. Each of stages 252a of FDC 252 and stages 256a of BDC 256 is configured to have the same delay time (t1). The delay time t1 is configured to be short to accommodate a high frequency application, while the number of stages is intended to be sufficient to accommodate a low frequency application. For example, when circuit chip 200 is operated at a high frequency, e.g., 200 MHz, the period Tck of external clock signal Ext Clk is 5 ns. To achieve a phase error of 5%, the delay time t1 of each stage is set at 0.25 ns. Assuming that the dummy delay 250 provides a delay of 4.8 ns, the delay introduced by FDC 252 or BDC 256 is Tck−(Td1+Td2+Td3)=5 ns−4.8 ns=0.2 ns, which is less than a delay of one stage (0.25 ns). Thus, the synchronization in the high frequency operation can be achieved by having the clock signal traverse only the first stage of FDC 252 and the last stage of BDC 256, as shown by an arrow 280 in FIG. 3A.

When circuit chip 200 is operated at a low frequency, e.g., 50 MHz, the external clock period Tck is 20 ns. Thus, each of FDC 252 and BDC 256 is configured to generate a delay equal to Tck−(Td1+Td2+Td3)=20 ns−4.8 ns=15.2 ns. Because the delay time t1 of each stage is 0.25 ns, each of FDC 252 and BDC 256 needs at least 61 stages to generate a sufficient delay. As shown by an arrow 282 in FIG. 3B, when circuit chip 200 is operated at 50 MHz, a clock signal traverses 61 stages of each of FDC 252 and BDC 256 to produce the required delay for synchronizing the external clock signal Ext Clk and the data output. While delay circuit 202 enables circuit chip 200 to operate at a wide range of frequency, it may occupy a relatively large circuit area of circuit chip 200, which can result in higher cost and power consumption.

Consistent with embodiments of this disclosure, a delay circuit is configured to include at least one FDC and at least one BDC. The FDC has a plurality of stages connected in series for a clock signal to traverse in a first direction, which introduce a delay in the clock signal. The BDC has a plurality of stages connected in series in a second direction different from the first direction, which introduce a further delay in the clock signal. The respective delay times of the stages of the FDC and BDC can be varied. In one embodiment, the respective delay times of the stages of the FDC increase in the forward direction, and the respective delay times of the stages of the BDC decrease in the backward direction. In another embodiment, the delay time of each stage in the FDC is shorter than that of the next stage in the forward direction, and the delay time of each stage in the BDC is longer than that of the next stage in the backward direction. In yet another embodiment, each of the FDC and BDC includes a plurality of groups of stages. Each group of stages includes one or more stages. The number of stages in each group can vary. The respective delay times of the stages can be the same within one group. The delay times of the respective groups of stages in the FDC increase in the forward direction, and the delay times of the respective groups of stages in the BDC decrease in the backward direction.

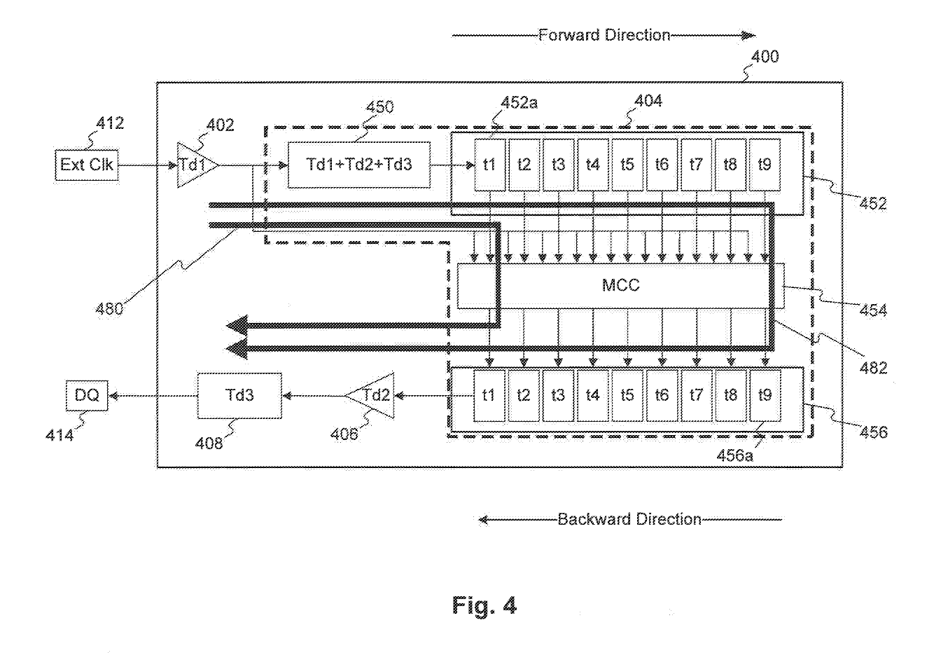

FIG. 4 shows a schematic diagram of an integrated circuit chip 400 consistent with an embodiment of the present disclosure. Circuit chip 400 includes an input buffer 402, a delay circuit 404, a clock driver 406, and an output buffer 408. Circuit chip 400 receives an external clock signal Ext Clk from an external clock 412 and outputs data to a data bus 414. In the illustrated embodiment, input buffer 402 receives the external clock signal and introduces an internal delay time period Td1. Clock driver 406 generates an internal clock signal Int Clk to control the output of data by output buffer 408. Clock driver 406 introduces an internal delay time period Td2. Output buffer 408, which introduces an internal delay time period Td3, is controlled by the internal clock signal Int Clk to output data to data bus 414.

Delay circuit 404 may be a synchronous mirror delay circuit that includes a dummy delay circuit 450, a forward delay circuit (FDC) 452, a mirror control circuit (MCC) 454, and a backward delay circuit (BDC) 456. Dummy delay circuit 450 is configured to delay a clock signal by a pre-determined time period. In the illustrated embodiment, dummy delay circuit 450 introduces a delay time of Td1+Td2+Td3, which equals a combined delay introduced by input buffer 402, clock driver 406, and output buffer 408, i.e., the other elements that introduce delay in circuit chip 400. FDC 452 includes nine gates (stages) 452a having delay times t1-t9. BDC 456 also includes nine gates 456a having delay times t1-t9. The respective delay times t1-t9 of gates 452a of FDC 452 increase in the forward direction, i.e., t9>t8>t7>t6>t5>t4>t3>t2>t1. The respective delay times t1-t9 of gates 456a of BDC 456 decrease in the backward direction, i.e., t9>t8>t7>t6>t5>t4>t3>t2>t1. As discussed above, delay circuit 404 is configured to introduce a delay so that the data output from output buffer 414 is synchronized with the external clock signal Ext Clk output by external clock 412. In circuit chip 400, the delay between the external clock signal Ext Clk and the data output is 2Tck, where Tck is one clock period of the external clock signal Ext Clk. Specifically, each of FDC 452 and BDC 456 introduces a delay equal to Tck−(Td1+Td2+Td3). Therefore, when circuit chip 400 is operated at high frequency and thus short Tck, the delays introduced by FDC 452 and BDC 456 can also be short. This is achieved by, for example, the clock signal traversing along arrow 480, which only traverses gates having a short delay t1 of FDC 452 and FDC 456. Because the beginning stages of FDC 452 or end stages of BDC 456 are configured to have short delay times, delay circuit 404 can provide high accuracy required by operation at high frequency.

When circuit chip 400 is operated at relatively low frequency, delay circuit 404 is required to introduce a longer delay for synchronizing the clock signals. Thus, the clock signal needs to traverse more gates in FDC 452 and BDC 456, as indicated by an arrow 482 in FIG. 4. In the illustrated embodiment, the clock signal traverses nine gates in each of FDC 452 and BDC 456. Because the gates in the forward direction of FDC 452 and the gates in the backward direction of BDC 456 are configured to have longer delay times, fewer gates are required for FDC 452 and BDC 456. As a result, delay circuit 404 can be designed to occupy less area of circuit chip 400. Further, since the clock signal traverses fewer gates and thus a shorter distance to produce sufficient delay, delay circuit 404 can provide fast locking and low power consumption.

In the illustrated embodiment, although nine gates (stages) are shown in FIG. 4, the disclosure is not so limited. The number of gates can be adjusted based on a desired operating frequency range. Further, the delay time of each gate can be modified to accommodate the needs of particular applications. Further, although input buffer 402, delay circuit 404, clock driver 406, and output buffer 408 are shown to be integrated in a single chip, i.e., circuit chip 400, they can be divided into discrete components working together in an electronic device. In addition, one or more of the elements of circuit chip 400 may be omitted to achieve a desired architecture. For example, an integrated circuit may include a receiving portion, such as input buffer 402, an output portion, such as output buffer 408, and delay circuit 404 that synchronizes a time when the input port receives a signal and a time when the output port outputs data.

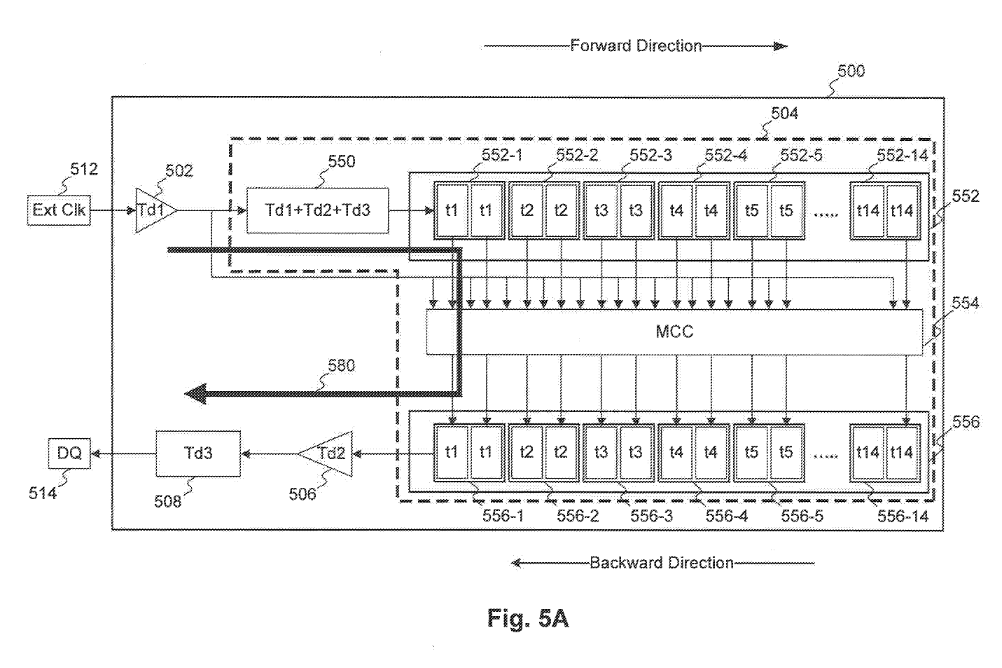

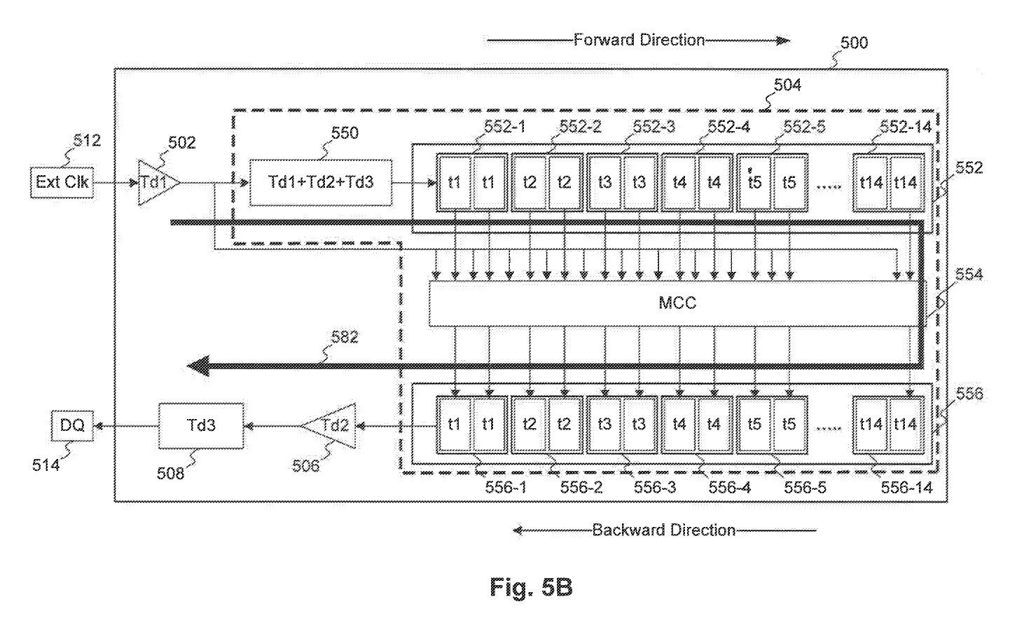

FIGS. 5A and 5B show schematic diagrams of a circuit chip 500, configured to operate at high and low frequencies, respectively. Circuit chip 500 includes an input buffer 502, a delay circuit 504, a clock driver 506, and an output buffer 508. Circuit chip 500 receives an external clock signal Ext Clk from an external clock 512 and outputs data to a data bus 514. Except for delay circuit 504, the structure and function of all of these elements are similar to those of circuit chips 400 and 200 and will not be described again. Delay circuit 504 may be a synchronous mirror delay circuit that includes a dummy delay circuit 550, a forward delay circuit (FDC) 552, a mirror control circuit (MCC) 554, and a backward delay circuit (BDC) 556. The structure and purpose of dummy delay circuit 550 and MCC 554 are similar to those of dummy delay circuit 450 and MCC 454 of circuit chip 400 and will not be described again. Each of FDC 552 and BDC 556 includes a plurality of groups of gates (stages). As shown in FIGS. 5A and 5B, FDC 552 includes fourteen groups 552-1, 552-2, 552-3, 552-4, 552-5, . . . , and 552-14; BDC 556 includes fourteen groups 556-1, 556-2, 556-3, 556-4, 556-5, . . . , and 556-14. Each of the groups includes two gates (stages) configured to have the same delay time. For example, each of the gates in group 552-1 has a delay time t1, each of the gates in group 552-2 has a delay time t2, etc. Delay times of groups 552-1, 552-2, 552-3, 552-4, 552-5, . . . , and 552-14 of FDC 552 increase in the forward direction. Delay times of groups 556-1, 556-2, 556-3, 556-4, 556-5, . . . , and 556-14 of BDC 556 decrease in the backward direction. That is, t14> . . . >t5>t4>t3>t2>t1. On this basis, accumulated delays after a clock signal traverses a group or groups are illustrated below in Table 1.

TABLE 1

| | | Stage n | Stage n + | Accumulated |
|---|---|---|---|---|
| Group | Stage n | Delay | 1 Delay | Delay |
| 1 | 1 | 0.25 | 0.25 | 0.5 |
| 2 | 3 | 0.3 | 0.3 | 1.1 |
| 3 | 5 | 0.35 | 0.35 | 1.8 |
| 4 | 7 | 0.4 | 0.4 | 2.6 |
| 5 | 9 | 0.45 | 0.45 | 3.5 |
| 6 | 11 | 0.5 | 0.5 | 4.5 |
| 7 | 13 | 0.55 | 0.55 | 5.6 |
| 8 | 15 | 0.6 | 0.6 | 6.8 |
| 9 | 17 | 0.65 | 0.65 | 8.1 |
| 10 | 19 | 0.7 | 0.7 | 9.5 |
| 11 | 21 | 0.75 | 0.75 | 11 |
| 12 | 23 | 0.8 | 0.8 | 12.6 |
| 13 | 25 | 0.85 | 0.85 | 14.3 |
| 14 | 27 | 0.9 | 0.9 | 16.1 |
| 15 | 29 | 0.95 | 0.95 | 18 |

In one embodiment, the delay times are set according to tₓ₊₁=tₓ+0.05 ns. Thus, t2=t1+0.05 ns, t3=t2+0.05 ns, etc. To accommodate an operating frequency of 200 MHz with a resolution of 5%, the minimum delay time t1 is set to be 0.25 ns. Assuming that dummy delay 550 provides a delay of 4.8 ns, the delay introduced by FDC 552 or BDC 556 can be calculated according to Tck−(Td1+Td2+Td3)=5 ns 4.8 ns=0.2 ns, which is less than the delay (0.25 ns) of the first stage in group 552-1 or the delay of the last stage of group 556-1. Thus, synchronization at this high operating frequency can be achieved by having the clock signal traverse only the first stage of FDC 552 and the last stage of BDC 556, as shown by an arrow 580 in FIG. 5A.

When circuit chip 500 is operated at low frequency, e.g., 50 MHz, the external clock period Tck is 20 ns. Accordingly, each of FDC 552 and BDC 556 is configured to generate a delay equal to Tck−(Td1+Td2+Td3)=20 ns 4.8 ns=15.2 ns. According to Table 1, the clock signal would traverse at least through the 14^{th} group or the 27^{th} stage of FDC 552 or BDC 556 to produce the required delay, as indicated by an arrow 582 shown in FIG. 5B. As compared to delay circuit 202 in FIG. 2C, delay circuit 504 in FIG. 5B needs substantially fewer stages to achieve sufficient delay. Because delay circuit 504 needs fewer stages to achieve synchronization, it can occupy less area of circuit chip 500. The resolution of circuit chip 500 operated at 50 MHz is less than 0.9 ns. A phase error of circuit chip 500 can be calculated as 0.9 ns/20 ns=4.5%. Thus, the illustrated embodiment further provides high accuracy synchronization.

Although the exemplary delay circuit 504 shown in FIGS. 5A and 5B includes fourteen groups and each group includes two stages, this disclosure is not so limited. The number of groups can be greater or less than fourteen, and the number of stages included in each group can be greater than two.

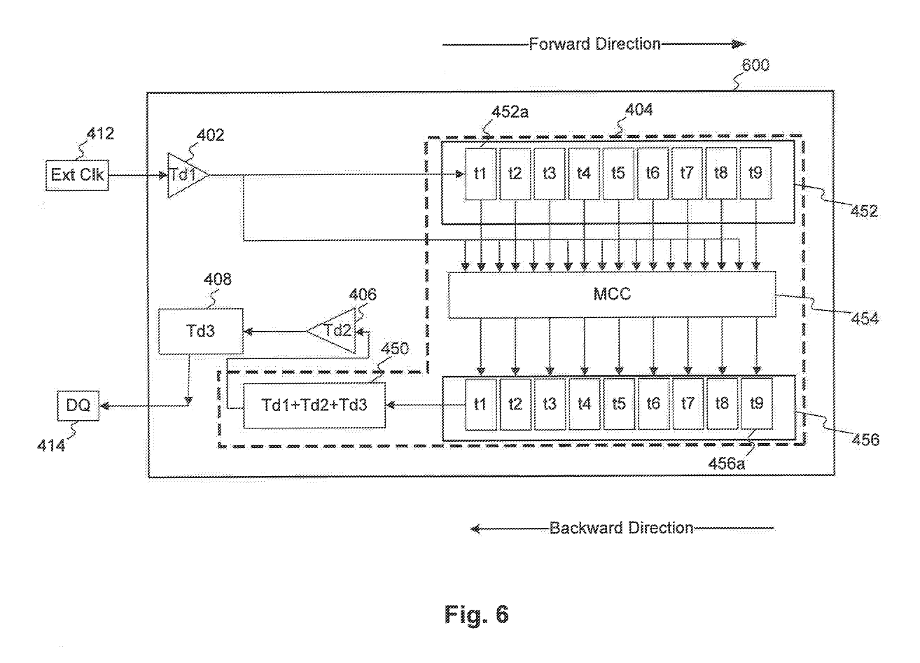

The delay times of the illustrated FDC 252, 452, 552 and BDC 256, 456, 556 can be accomplished by a resistive-capacitive delay, a propagation delay caused by, for example, a resistor, or any kind of charge and discharge structure such as a capacitor. In the illustrated embodiments, although dummy delay circuits 250, 450, 550 are coupled at an input end of FDC 252, 452, 552, dummy delay circuits 250, 450, 550 can instead be coupled at an output end of BDC 256, 456, 556. An example is shown in FIG. 6, which shows an exemplary integrated circuit chip 600. Circuit chip 600 is similar to circuit chip 400 except that circuit chip 600 includes a dummy delay circuit 450 coupled to an output of BDC 456. Similar to the delay times described with reference to delay circuit 404 in FIG. 4, the respective delay times t1-t9 of FDC 452 and BDC 456 decrease from t9 to t1 as: t9>t8>t7>t6>t5>t4>t3>t2>t1. In some embodiments, a delay circuit may include multiple dummy delay circuits coupled in various locations in the delay circuit.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An electronic circuit, comprising:
a forward delay circuit having a plurality of first stages, each of the first stages being configured to introduce a delay time, the delay times of the first stages being varied;
a control circuit coupled to the forward delay circuit; and
a backward delay circuit coupled to the control circuit and having a plurality of second stages, each of the second stages being configured to introduce a delay time, the delay times of the second stages being varied.

2. The electronic circuit according to claim 1, wherein the first stages of the forward delay circuit are coupled in series in a forward direction of signal propagation, and the second stages of the backward delay circuit are coupled in series in a backward direction of signal propagation.

3. The electronic circuit according to claim 2, wherein the delay times of respective first stages increase in the forward direction.

4. The electronic circuit according to claim 2, wherein the delay times of respective second stages decrease in the backward direction.

5. The electronic circuit according to claim 2, wherein a first delay time of a first stage in the forward delay circuit is shorter than a second delay time of a next first stage in the forward direction.

6. The electronic circuit according to claim 5, wherein a third delay time of a second stage in the backward delay circuit is longer than a fourth delay time of a next second stage in the backward direction.

7. The electronic circuit according to claim 2, wherein the plurality of first stages are divided into a plurality of first groups, each of the first groups includes one or more first stages having a same delay time, and respective delay times of the first groups increase in the forward direction.

8. The electronic circuit according to claim 7, wherein the plurality of second stages are divided into a plurality of second groups, each of the second groups includes one or more second stages having a same delay time, and respective delay times of the second groups decrease in the backward direction.

9. The electronic circuit according to claim 1, further comprising a dummy delay circuit coupled to an input of the forward delay circuit or an output of the backward delay circuit.

10. The electronic circuit according to claim 1, wherein the forward and backward delay circuits are configured so that a number of first stages and second stages that a signal traverses is configured to increase as an operating frequency of the electronic circuit decreases.

11. An integrated circuit, comprising:
an input port to receive a signal;
an output buffer to output data; and
a delay circuit coupled to the input port and the output buffer, the delay circuit being configured to coordinate a first time when the input port receives the signal with a second time when the output buffer outputs the data, wherein the delay circuit includes:
a forward delay circuit having a plurality of first stages, each of the first stages being configured to introduce a delay time, the delay times of the first stages being varied;
a control circuit coupled to the forward delay circuit; and
a backward delay circuit coupled to the control circuit and having a plurality of second stages, each of the second stages being configured to introduce a delay time, the delay times of the second stages being varied.

12. The integrated circuit according to claim 11, wherein the first stages of the forward delay circuit are coupled in series in a forward direction of signal propagation, and the second stages of the backward delay circuit are coupled in series in a backward direction of signal propagation.

13. The integrated circuit according to claim 12, wherein the delay times of respective first stages increase in the forward direction.

14. The integrated circuit according to claim 12, wherein the delay times of respective second stages decrease in the backward direction.

15. The integrated circuit according to claim 12, wherein a first delay time of a first stage in the forward delay circuit is shorter than a second delay time of a next first stage in the forward direction.

16. The integrated circuit according to claim 15, wherein a third delay time of a second stage in the backward delay circuit is longer than a fourth delay time of a next second stage in the backward direction.

17. The integrated circuit according to claim 12, wherein the plurality of first stages are divided into a plurality of first groups, each of the first groups includes one or more first stages having a same delay time, and respective delay times of the first groups increase in the forward direction.

18. The integrated circuit according to claim 17, wherein the plurality of second stages are divided into a plurality of second groups, each of the second groups includes one or more second stages having a same delay time, and respective delay times of the second groups decrease in the backward direction.

19. The integrated circuit according to claim 11, wherein the forward and backward delay circuits are configured so that a number of first stages and second stages that a signal traverses is configured to increase as an operating frequency of the electronic circuit decreases.

20. A circuit chip, comprising:
an input buffer to receive a first clock signal;
an output buffer to output data;
a clock driver to generate a second clock signal to control the output buffer to output the data, and
a delay circuit coupled between the input buffer and the clock driver, the delay circuit being configured to coordinate a first time when the input buffer receives the first clock signal with a second time when the output buffer outputs the data, wherein the delay circuit includes:
a forward delay circuit having a plurality of first stages, each of the first stages being configured to introduce a delay time, the delay times of the first stages being varied;
a control circuit coupled to the forward delay circuit; and
a backward delay circuit coupled to the control circuit and having a plurality of second stages, each of the second stages being configured to introduce a delay time, the delay times of the second stages being varied.
